(19) United States
(12) Patent Application Publication
(10) Pub. No.: US 2008/0296604 A1
(43) Pub. Date: Dec. 4, 2008

(54) LIGHT-EMITTING DIODE LEAD FRAME AND MANUFACTURE METHOD THEREOF

(75) Inventors: Wan-Shun Chou, Sinjhuang City (TW); Hsin-Chang Chu, Sinjhuang City (TW); Ming-Chin Chang, Sinjhuang City (TW); Hsi-Chen Hsihe, Sinjhuang City (TW)

Correspondence Address: Muncy, Geissler, Olds & Lowe, PLLC, P.O. BOX 1364, FAIRFAX, VA, 22038-1364, US

(73) Assignee: I-CHIUN PRECISION INDUSTRY CO., LTD.

(21) Appl. No.: 12/127,309

(22) Filed: May 27, 2008

(30) Foreign Application Priority Data
May 30, 2007 (TW) 096119272

(51) Int. Cl. H01L 33/00; H01L 21/50

(52) U.S. Cl. 257/99; 438/26; 257/E33.056; 257/E21.499

(57) ABSTRACT

The invention discloses an LED lead frame and the manufacture method thereof. First, a press-formed strip including a guide strip, a first metal frame, and a second metal frame is provided. The first metal frame and the second metal frame are connected to the guide strip and are connected to each other via a connection part. The first metal frame includes a first region. The second metal frame includes a second region. The connection part includes a third region. Then, the press-formed strip is clipped by a fixture such that the first region and the second region are exposed. Then, the press-formed strip is put in an electroplate solution and an electroplate layer is plated on the first region and the second region, but not on the third region. At last, the fixture is removed. The LED lead frame is then obtained.

### BACKGROUND OF THE INVENTION

1. Field of the Invention

The invention relates to the lead frame a light emitting diode (LED) and the manufacture method thereof. More particularly, the invention is relative to an LED lead frame that is selectively plated and the manufacture method thereof.

2. Description of the Prior Art

In the known manufacture method of LED devices, a metal plate is first pressed to form a plurality of electrodes and a plurality of pins extended from the electrodes. Then, a cuplike insulator is formed by inserted-molding process and is connected to the electrodes and pins. The LED chip is fixed in the cuplike insulator and is electrically connected to the electrodes by wire-bonding. Typically, the cuplike insulator is subsequently packaged by the polyepoxide. After the process of forming external pins, an LED device can be obtained.

In order to improve the electrical property of LED devices, an electroplate layer is usually plated on the electrodes and pins before the inserted-molding process. However, during manufacture processes, most semi-finished LED devices are connected on strips. The strip includes a plurality of frames, and each frame is used for forming an LED device. There are connection parts for connecting the adjacent frames. Typically, the strip also includes a guide strip. In the aforementioned plating procedure, not only the electrodes and pins but also the connection parts, and even the guide strip, are plated. However, the connection parts and the guide strip are not parts of the finish products, and plating on them is wasteful and non-effective for the production. The waste is not allowed especially when precious metals are used in the plating procedure. On the other hand, reducing the galvanization quantity can reduce the pollution and is helpful to the environmental protection.

Therefore, LED manufacture methods for preventing or lowering the above problems are in demand.

### SUMMARY OF THE INVENTION

A scope of the invention is to provide an LED lead frame and the manufacture method thereof.

Another scope of the invention is to provide a selectively plated LED lead frame and the manufacture method thereof.

The LED lead frame of the invention includes a guide strip, a first metal frame, a second metal frame, and a connection part. The first metal frame is connected to the guide strip and has a first region. The second metal frame is connected to the guide strip and has a second region. The connection part, connected between the first metal frame and the second metal frame, has a third region. A first electroplate layer is plated on the first region and the second region, but not on the third region.

In an embodiment, the first metal frame includes a first metal substrate and a second metal substrate. The first metal frame includes at least one electrode slice and a pin extended from one side of the at least one electrode slice. The second metal frame includes a base. The first metal frame is engaged with the second frame, such that the base is adjacent to the at least one electrode slice and there is a gap between the base and the at least one electrode slice.

In addition, two cuplike insulators are respectively disposed on the first metal frame and the second metal frame of the LED lead frame according to the invention, such that the first region and the second region are exposed. The LED lead frame further includes at least one LED chip, which is disposed in the cuplike insulator. A package glue is also disposed in the cuplike insulator and covers the at least one LED chip. The package glue includes phosphor powders.

On the other hand, the first metal frame includes a through-hole. The first metal frame has a first surface and a second surface opposite to the first surface. The first electroplate layer is plated on the first surface. The LED lead frame further includes a second electroplate layer which is plated on the second surface.

In the manufacture method of an LED lead frame according to the invention, a press-formed strip including a guide strip, a first metal frame, a second metal frame, and a connection part is provided. The first metal frame is connected to the guide strip and has a first region; the second metal frame is connected to the guide strip and has a second region. The first metal frame is connected to the second metal frame via the connection part. The connection part has a third region. Then a fixture is provided for clipping the press-formed strip such that the first region and the second region are exposed. Subsequently, the press-formed strip is put in an electroplate solution and a first electroplate layer is plated on the first region and the second region, but not on the third region. The fixture is then removed. In the plating step, the electroplate solution is poured into the fixture by a pressure pump to cover the first region and the second region. The fixture can be made of silicone or other materials which have the erosion resistance to the electroplate solution.

In an embodiment, the first metal frame includes a first metal substrate and the second metal substrate. The first metal substrate includes at least one electrode slice and a pin extended from one side of the at least one electrode slice. The second metal substrate includes a base. The second metal substrate is engaged with the first metal substrate such that the base is adjacent to the at least one electrode slice and there is a gap between the base and the at least one electrode slice. The first region includes the at least one electrode slice, the pin, and the base.

In addition, the first metal frame has a first surface and a second surface opposite to the first surface. The first electroplate layer is plated on the first surface. When the first metal frame includes a through-hole, the above plating step can further include making the electroplate solution flow through the through-hole to cover the second surface and plating a second electroplate layer on the second surface.

Besides, after the fixture is removed, the manufacture method can further include the step of inserted-molding a cuplike insulator on the press-formed strip, wherein the cuplike insulator is connected to the first metal frame such that the first region is exposed. And the manufacture method of LED lead frame further includes the following steps: fixing an LED chip in the cuplike insulator, wherein the LED chip includes an electrode; electrically connecting the electrode with at least one electrode slice via a metal wire; and filling the cuplike insulator with a package glue to cover the LED chip.

The invention can manufacture an LED lead frame including a non-electroplated region with a plurality of streaks, especially streaks perpendicular to the guide stripe. Further, the invention prevents the ineffective region from being plated, so as to save the electroplate cost.

The advantage and spirit of the invention may be understood by the following recitations together with the appended drawings.

### BRIEF DESCRIPTION OF THE APPENDED DRAWINGS

FIG. 1(A) is a schematic diagram illustrating an LED lead frame in an embodiment.

FIG. 1(B) illustrates a partial enlarged diagram of FIG. 1(A)

FIG. 1(C) is a schematic diagram illustrating an electroplate layer of the LED lead frame.

FIG. 1(D) is a schematic diagram illustrating another distribution of the electroplate layer of the LED lead frame.

FIG. 1(E) is a schematic diagram illustrating another distribution of the electroplate layer of the LED lead frame.

FIG. 1(F) is a schematic diagram illustrating the cover range of metal frame of the LED lead frame.

FIG. 2 is an oblique view illustrating the LED lead frame according to an embodiment.

FIG. 3(A) is a schematic diagram illustrating the LED lead frame according to another embodiment.

FIG. 3(B) is a schematic diagram illustrating a first metal substrate in the embodiment.

FIG. 3(C) is a schematic diagram illustrating a second metal substrate in the embodiment.

FIG. 4 is a flow chart illustrating a method of manufacturing the LED lead frame according to the invention.

### DETAILED DESCRIPTION OF THE INVENTION

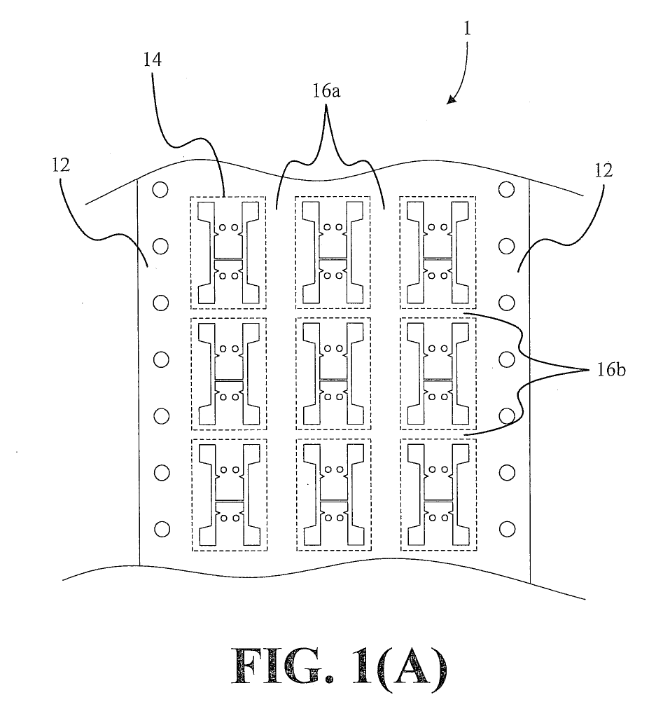

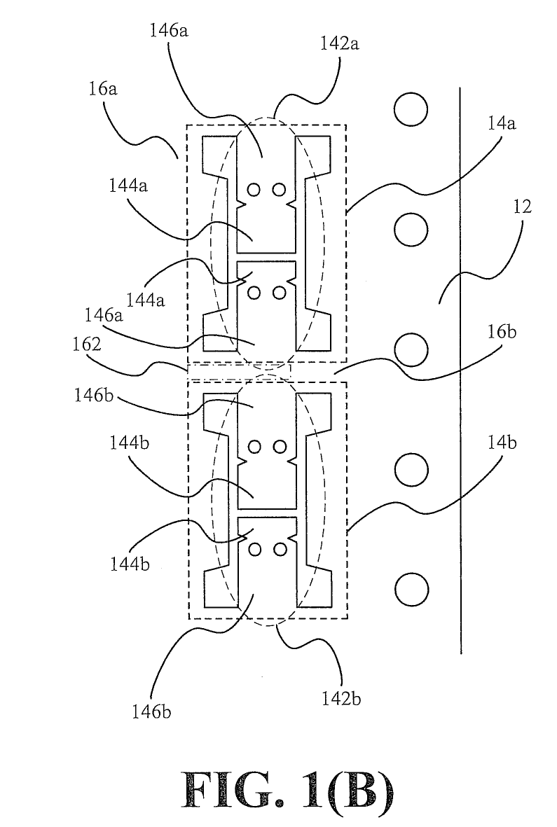

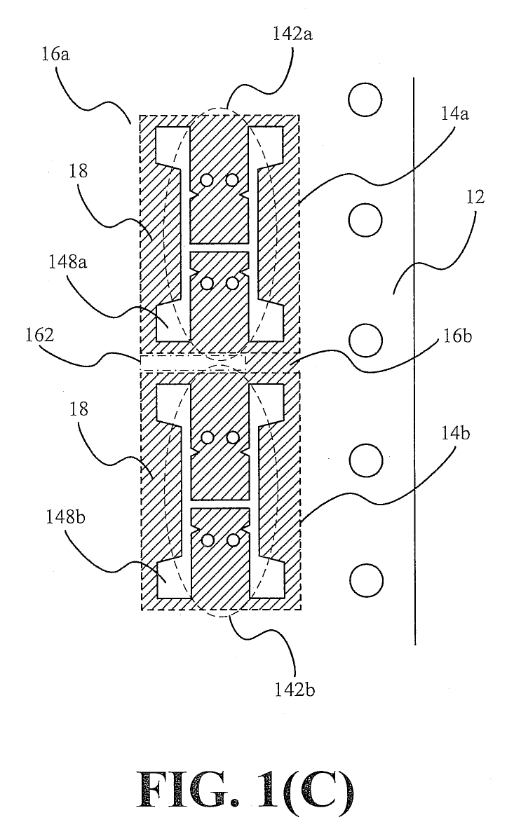

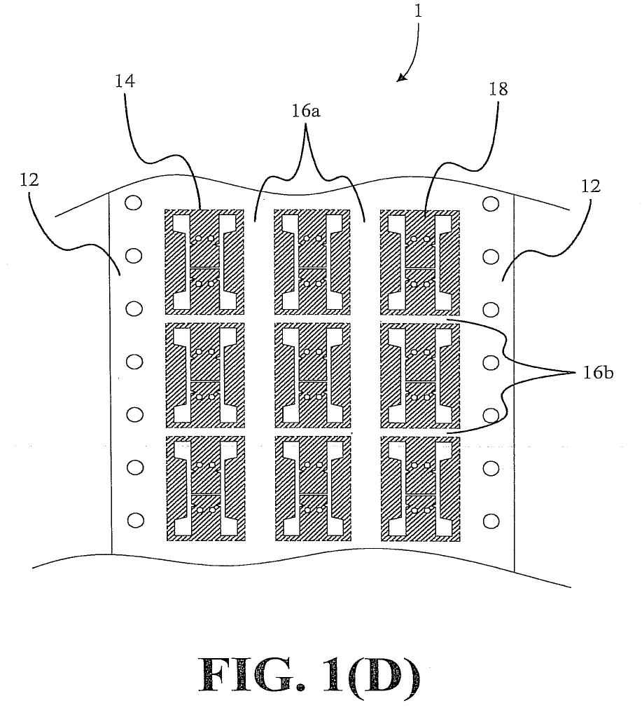

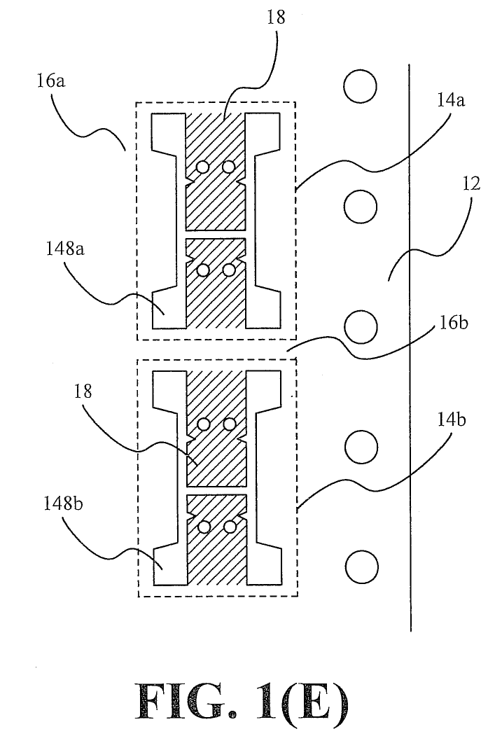

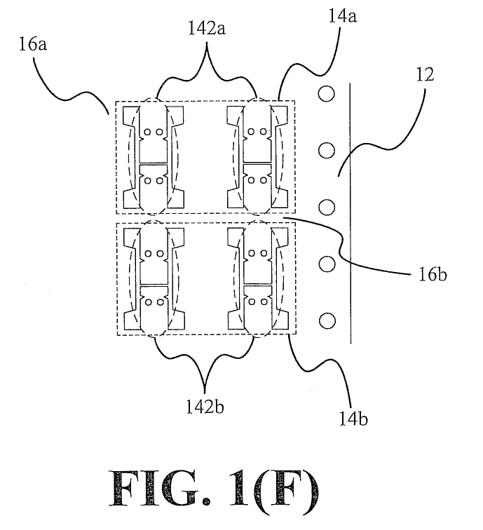

Please refer to FIG. 1(A), which is a schematic diagram illustrating an LED lead frame 1 in an embodiment. The LED lead frame 1 of the invention includes a guide strip 12, nine metal frames 14 (shown in the dashed blocks). The metal frames 14 adjacent to the guide strip 12 are connected guide strip 12, and the adjacent metal frames 14 are connected to each other via a connection part 16a or 16b.

Please refer to FIG. 1(B), which illustrates a partial enlarged diagram of FIG. 1(A). FIG. 1(B) shows two adjacent metal frames 14a and 14b, a connection part 16b for connecting the metal frames 14a and 14b, and the guide strip 12. The metal frames 14a and 14b respectively include a region 142a and 142b (shown as dashed ellipse). The regions 142a and 142b usually include electrode slices 144a, 144b, and pins 146a and 146b extended from the electrode slices, but are not limited to these parts. Besides, the connection part 16b includes the region 162. The region 162 usually includes the whole connection part 16b, but is not limited to it. In addition, the electroplated regions 142a and 142b and the non-electroplated region 162 do not have to be continuous regions; these regions can also be a set of discrete regions.

Please refer to FIG. 1(C), which is a schematic illustrating an electroplated region of LED lead frame 1 (shown as slanted line). The LED lead frame 1 of the invention includes an electroplate layer 18. The first electroplate layer 18 is plated on the regions 142a and 142b, but not on the region 162. In addition, the metal frames 14a and 14b include through-holes 148a and 148b. The LED lead frame 1 further includes a second electroplate layer (not shown). The LED lead frame 1 thereon defines a first surface (not labeled) and a second surface (not shown) opposite to the first surface. The first electroplate layer 18 is plated on the first surface, and the second electroplate layer is plated on the second surface. The electroplate solution flows through the through-holes 148a and 148b to the second surface and a second electroplate layer can accordingly being plated on the second surface. The through-holes 148a and 148b can be hollowed-out regions of the metal frame 14. Therefore, the invention is not limited to the condition with only one electroplated surface. The material of the first electroplate layer 18 can be gold, silver, copper, tin, nickel, other metals, or alloy. Besides, the first electroplate layer 18 is not limited to a single-layer structure; it can also has a multi-layer structure. For example, a copper layer can be first plated on a brass base. A nickel layer and a tin layer are subsequently plated above the copper layer.

The electroplate layer of the LED lead frame 1 of the invention can be plated only on the required regions, and plating on an unnecessary region (for instance, the connection parts 16a and 16b, and the guide strip 12) is prevented. Besides, please refer to FIG. 1(D), which illustrates the condition that the electroplate layer is plated only on the metal frame 14. As shown in FIG. 1(D), not only the connection part 16a, which is parallel to the guide strip 12, does not have to be plated, but also the connection part 16b perpendicular to the guide strip 12. The cost of plating can be accordingly reduced. Although it is not necessary for the non-electroplated region 162 to include the whole connection part 16b, the electroplate layer can be substantially limited in the required region (for instance, regions 142a and 142b) by properly designing the fixture used in the plating process. Based on designing requirements, the distribution of the electroplate layer 18 can also be the one shown in FIG. 1(E). Additionally, in order to decrease the plated region of connection parts 16a and 16b, through-holes can be formed on the connection parts 16a and 16b.

It should be noted that the metal frame of an LED lead frame according to the invention can be provided not only for forming a single LED device, but also a plurality of LED devices, as shown in FIG. 1(F).

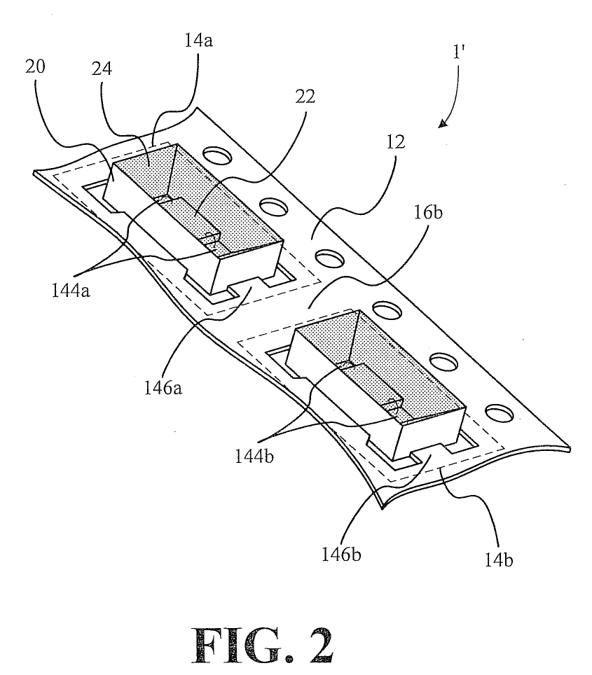

Please refer to FIG. 2, which illustrates an oblique view of an LED lead frame 1′ in an embodiment according to the invention. FIG. 2 shows only a part of the LED lead frame 1′. Compared with the aforementioned embodiment, LED lead frame 1′ further includes a cuplike insulator 20. The cuplike insulator 20 is connected with the metal frame 14a such that the region 142a is exposed. It should be noted that it is not necessary to expose the entire region 142a, and the parts to be exposed can be determined based on the design of products. Besides, the LED lead frame 1′ further includes an LED chip 22 disposed in the cuplike insulator 20. The electrode of LED chip 22 is electrically connected to the electrode slice 144a of metal frame 14a. The number of LED chips disposed in the cuplike insulator 20 is not limited to one. In addition, the LED lead frame 1′ further includes a package glue 24 (shown as a dot region); phosphor powder can be included in the package glue 24. The package glue 24 is used for packaging the LED chip 22, and it is not necessary to fill the cuplike insulator 20 with the package glue 24.

In the aforesaid embodiments, the adjacent metal frames 14a and 14b are the same. In other embodiments, the structure of metal frames 14a and 14b can be different and designed based on actual needs; hence, different LED devices can be manufactured thereon. In addition, in FIG. 1(B), the region 142a of metal frame 14a and the region 142b of metal frame 14b are the same. Even if the geometric structure of the metal frames 14a and 14b are the same, the regions 142a and 142b can also be different based on the need of designers. Besides, the regions 142a and 142b in other embodiments do not have to be located on the same plane. For instance, the electrode slices 144a and 144b can be higher or lower than the pins 146a and 146b, or can even be bended.

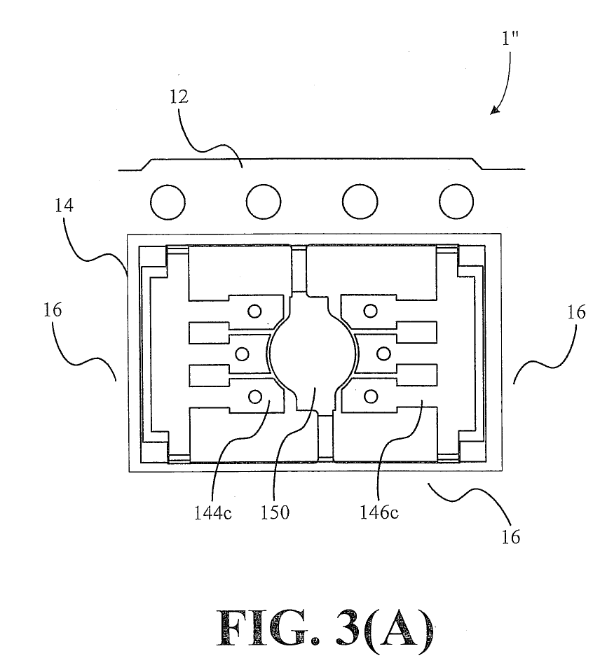

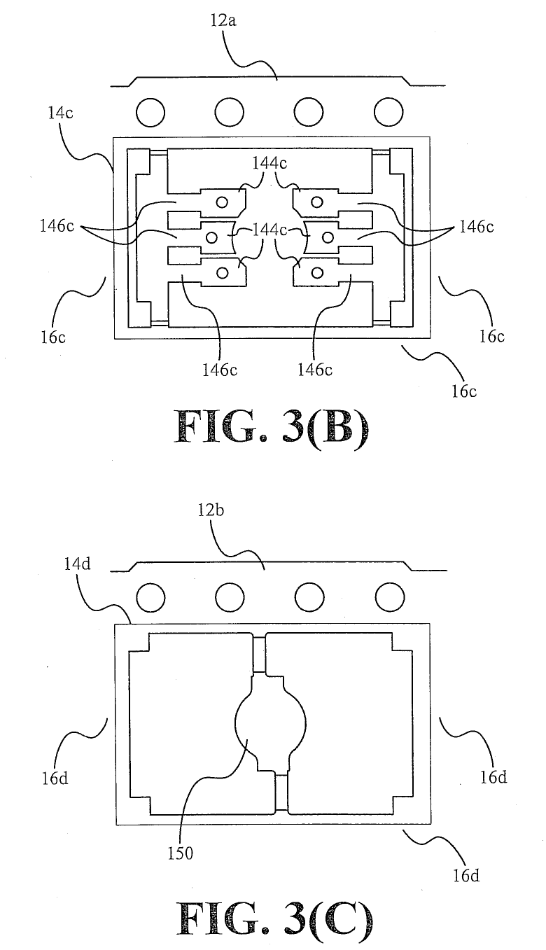

Besides, in the aforesaid embodiments, the metal frames 14a and 14b are made of the same metal plate, and it is a general structure of LED lead frames, but the invention is not limited to this. Please refer to FIG. 3(A), which illustrates a schematic diagram of an LED lead frame 1″ according to another embodiment. FIG. 3(A) is only shows one part of the LED lead frame 1″. Compared with the aforesaid embodiment, the metal frame 14 of LED lead frame 1″ is primarily includes a first metal substrate 14c and a second metal substrate 14d. Please also refer to FIG. 3(B) and FIG. 3(C). FIG. 3(B) illustrates a schematic diagram of the first metal substrate 14c; FIG. 3(C) illustrates a schematic diagram of the first metal substrate 14d. The first metal substrate 14c includes six electrode slices 144c and pins 146c extended from one side of the electrode slices 144c; the second metal substrate 14d includes a base 150. The first metal substrate 14c is engaged with the second metal substrate 14d, and there is a gap between the base 150 and the electrode slice 144c adjacent to the base 150, as shown in FIG. 3(A).

The guide strip 12a of the first metal substrate 14c is engaged with the guide strip 12b of the second metal substrate 14d to form a guide strip 12. Similarly, the connection part 16c of the first metal substrate 14c and the connection part 16d of the second metal substrate 14d are engaged to each other and form a connection part 16. The connection parts 16c and 16d could be repeatedly engaged or interlaced. The first electroplate layer 18 (not shown in FIG. 3(A)) is plated on the required region, such as the electrode slices 144c, base 150, and pins 146c. Therefore, the invention can also be applied in the LED lead frame including a plurality of metal substrates.

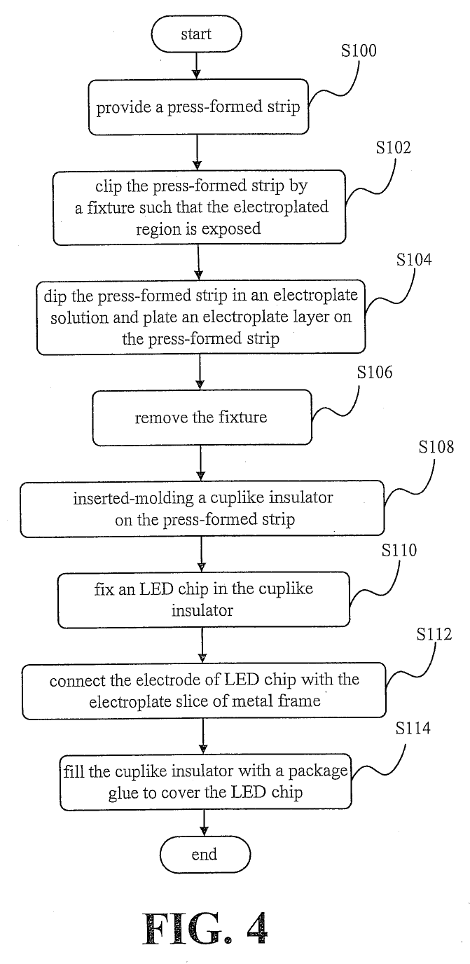

Please refer to FIG. 4, which illustrates a flow chart of a method for manufacturing the aforesaid LED lead frame 1. In this method, a press-formed strip is first provided (step S100). The press-formed strip is the aforesaid LED lead frame 1 before the plating and inserted-molding processes. Then, in step S102, a fixture is used to clip the press-formed strip such that the regions to be plated (142a and 142b) are exposed. In step S104, the press-formed strip is dipped in an electroplate solution to plate the first electroplate layer 18 on the regions 142a and 142b, but not on the region 162. In step S106, the fixture is removed.

In addition, the ingredients of the electroplate solution depends on the required first electroplate layer 18. The electroplate solution can be filled in the fixture by a pressure pump to shorten the time for the electroplate solution to cover the press-formed strip. If a multilayer structure is required, the press-formed strip can be sequentially dipped into different electroplate solutions. The process of forming multilayer structures is well known and is not further described herein. On the other hand, the fixture can be made of silicone or other materials endurable the erosion by the electroplate solution. By utilizing the fixture to clip the press-formed strip, the electroplated and non-electroplated regions can be clearly separated. Besides, a fixture made of elastic materials can be used to obtain better fitness between the press-formed strip and the fixture.

In another embodiment, the step S104 can further include making the electroplate solution flow through the through-holes 148a and 148b to cover the second surface, so as to plate a second electroplate layer on the second surface. On the other hand, after the step S106, the method for manufacturing the LED lead frame can include inserted-molding the cuplike insulator 20 on the press-formed strip (step S108); the regions 142a and 142b are still exposed. The method can further include the step of fixing the LED chip 22 in the cuplike insulator 20 (step S110). And then, the electrode of LED chip 22 is electrically connected with the electrode slices 144a and 144b of the metal frame 14a via a metal wire (step S112). The number of LED chips 22 is not limited to one. The method can also include the step of filling the cuplike insulator 20 with package glue 24 to cover the LED chip 22 (step S114); it is not necessary to completely fill the cuplike insulator 20 with the package glue 24.

In addition, the aforesaid metal frame of LED lead frame 1″ primarily includes two metal substrates. Each of the metal substrates is originally formed on a respective metal strip. Therefore, before the metal strips are engaged, required electroplate layers can be respectively plated on the metal strips. The process can be applied to the LED lead frame 1″ containing different electroplate layers, such as a gold-plated base 150, gold-plated electrode slices 144c, and silver-plated pins 146c. It should be noted that different fixtures can utilize to limit the plated region of press-formed strip. By utilizing different fixtures to limit non-electroplated regions and repeating the aforesaid steps S104 and S106 can obtain various electroplate layers of different materials for different applications. Besides, the invention is not limited to the LED lead frame 1″ described herein.

To sum up the above descriptions, the LED lead frame and manufacture method thereof according to the invention can effectively decrease the unnecessary electroplated region on the LED lead frame. Besides, the designer can further design the patterns of the electroplated region by designing different fixtures; the design of electroplated regions is not limited in one-dimension as the prior art is. In prior arts, the designer can only control the not-to-be-plated distance parallel to the guide strip. Hence, a non-electroplated region with a plurality of streaks on an LED lead frame, especially streaks perpendicular to the guide stripe, can not be manufactured in prior arts. The LED lead frame and manufacture method of the invention indeed can prevent the unnecessary region to be electroplated, so as to save the plating cost.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A light emitting diode (LED) lead frame, comprising:
a guide strip;
a first metal frame, connected to the guide strip, having a first region;
a second metal frame, connected to the guide strip, having a second region;
a connection part, connected between the first metal frame and the second metal frame, having a third region; and
a first electroplate layer plated on the first region and the second region, but not on the third region.

2. The LED lead frame of claim 1, wherein the first metal frame comprises a first metal substrate and a second metal substrate, the first metal substrate comprises at least one electrode slice and a pin extended from one side of the at least one electrode slice; the second metal substrate comprises a base, and the second metal substrate is engaged with the first metal substrate such that the base is adjacent to the at least one electrode slice and there is a gap between the base and the at least one electrode slice.

3. The LED lead frame of claim 1, wherein a cuplike insulator is disposed on the first metal frame such that the first region is exposed.

4. The LED lead frame of claim 3, wherein a package glue and at least one LED chip are disposed in the cuplike insulator, and the package glue comprises a phosphor powder that covers the at least one LED chip.

5. The LED lead frame of claim 1, wherein the first metal frame comprises a through-hole, the first metal frame has a first surface and a second surface opposite to the first surface, the first electroplate layer is plated on the first surface, the LED lead frame further comprising a second electroplate layer plated on the second surface.

6. A method for manufacturing a light emitting diode (LED) lead frame, comprising the steps of:
(a) providing a press-formed strip which comprises:
a guide strip;
a first metal frame, connected to the guide strip, having a first region;
a second metal frame, connected to the guide strip, having a second region; and
a connection part, connected between the first metal frame and the second metal frame, having a third region;
(b) clipping the press-formed strip by a fixture such that the first region and the second region are exposed;
(c) dipping the press-formed strip in an electroplate solution to plate a first electroplate layer on the first region and the second region, but not on the third region; and
(d) removing the fixture.

7. The method of claim 6, wherein the first metal frame comprises a through-hole, the first metal frame has a first surface and a second surface opposite to the first surface, the first electroplate layer is plated on the first surface, and step (c) comprises the steps of making the electroplate solution flow through the through-hole to cover the second surface and plating a second electroplate layer on the second surface.

8. The method of claim 6, wherein the fixture is made of silicone.

9. The method of claim 6, after step (d), the method further comprising the step of inserted-molding a cuplike insulator on the press-formed strip, wherein the cuplike insulator is connected to the first metal frame such that the first region is exposed.

10. The method of claim 9, wherein the first metal frame comprises a first metal substrate and a second metal substrate, the first metal substrate comprises at least one electrode slice and a pin extended from one side of the at least one electrode slice; the second metal substrate comprises a base and is engaged with the first metal substrate such that the base is adjacent to the at least one electrode slice and there is a gap between the base and the at least one electrode slice, after the step of inserted-molding, the method further comprising the steps of:
fixing an LED chip in the cuplike insulator, wherein the LED chip comprises an electrode;
electrically connecting the electrode with at least one electrode slice via a metal wire; and
filling the cuplike insulator with a package glue to cover the LED chip.
